(19) United States
(12) Patent Application Publication
(10) Pub. No.: US 2004/0132238 A1
(43) Pub. Date: Jul. 8, 2004

(54) Semiconductor device and manufacturing method thereof

(75) Inventors: Taichi Hirokawa, Hyogo (JP); Yusuke Kawase, Hyogo (JP); Akira Matsumura, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/640,335

(22) Filed: Aug. 14, 2003

(30) Foreign Application Priority Data
Jan. 8, 2003 (JP) 2003-002245(P)

(51) Int. Cl. H01L 21/336

(52) U.S. Cl. 438/197

(57) ABSTRACT

Each of contact plugs has an area of an upper surface larger than that of a lower surface. With this, better connections between contact plugs and plugs connected to upper surfaces of contact plugs are achieved. Therefore, a semiconductor device which can enhance a characteristic and a manufacturing method thereof are obtained.

### BACKGROUND OF THE INVENTION

1. Field of the Invention

The present invention relates to a semiconductor device including a contact plug connected to a semiconductor substrate between gate electrodes and a manufacturing method thereof.

2. Description of the Background Art

There is a conventional technique regarding a semiconductor device having a contact plug connected to a semiconductor substrate between gate electrodes formed on the semiconductor substrate and a manufacturing method thereof.

In the above-described semiconductor device, however, because of size reduction of the semiconductor device, a space between the gate electrodes becomes smaller, and an area of the contact plug in a direction parallel to a main surface of the semiconductor substrate becomes smaller. Thus, a plug connected to an upper surface of the contact plug is sometimes formed on a position deviated from the upper surface of the contact plug. As a result, a contact resistance may increase when an electrical connection between the contact plug and the plug is not in good condition.

### SUMMARY OF THE INVENTION

An object of the present invention is to enhance a characteristic of a semiconductor device by achieving a better connection between a contact plug connected to a semiconductor substrate and a plug connected to an upper surface of the contact plug.

A semiconductor device according to the present invention includes a semiconductor substrate and a first gate insulator film and a first gate electrode formed on the semiconductor substrate. The semiconductor device also includes a second gate insulator film and a second gate electrode formed on the semiconductor substrate and provided so as to extend in parallel with an extending direction of the first gate insulator film and first gate electrode.

In addition, the semiconductor device includes a first insulator film formed to cover surfaces of the first gate insulator film and first gate electrode and a second insulator film formed to cover surfaces of the second gate insulator film and second gate electrode.

A contact plug connected to an impurity diffusion region of the semiconductor substrate is provided within a contact hole formed with surfaces of the first and second insulator films. An area of the contact plug in a direction parallel to a main surface of the semiconductor substrate is larger on an upper surface than on a lower surface thereof.

According to the structure described above, a good connection between the contact plug and the plug connected to the upper surface of the contact plug is more easily achieved. As a result, a contact resistance between the plugs can decrease, and thus the characteristic of the semiconductor device is enhanced.

A manufacturing method of a semiconductor device according to one aspect of the present invention is as follows.

A first insulator film as a gate insulator film is formed on a semiconductor substrate. A conductive film as a gate electrode is then formed on the first insulator film. Thereafter, a second insulator film as a hard mask is formed on the conductive film. A first resist film having a prescribed pattern is formed on the second insulator film. Thereafter, a portion from an upper surface of the second insulator film to a prescribed depth is removed using the first resist film as a mask to form a portion protruding in a direction to leave from a main surface of the semiconductor substrate in the second insulator film. The first resist film is then removed. Thereafter, a second resist film is formed on the protruding portion with a width smaller than that of an upper surface of the protruding portion. The second insulator film is then etched using the second resist film as a mask to expose a surface of the conductive film to form a convex hard mask. Thereafter, the conductive film and the first insulator film are etched using the convex hard mask as a mask to expose the semiconductor substrate.

A manufacturing method of a semiconductor device according to another aspect of the present invention is as follows.

A first insulator film as a gate insulator film is formed on a semiconductor substrate. A conductive film as a gate electrode is then formed on the first insulator film. Thereafter, a second insulator film as a hard mask is formed on the conductive film. A polycrystalline silicon film is then formed on the second insulator film. A resist film having a prescribed pattern is formed on the polycrystalline silicon film. The polycrystalline silicon film is then anisotropically etched using the resist film as a mask to expose the second insulator film. Thereafter, the second insulator film is isotropically etched using the anisotropically-etched polycrystalline silicon film as a mask to form a projecting portion in the second insulator film below the anisotropically-etched polycrystalline silicon film. The second insulator film is then anisotropically etched using the resist film and the anisotropically-etched polycrystalline silicon film as a mask to form the second insulator film into convex shape. The resist film and the anisotropically-etched polycrystalline silicon film are then removed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a structure of a semiconductor device according to a first embodiment.

FIGS. 2-15 are diagrams for describing a manufacturing method of the semiconductor device according to the first embodiment.

FIG. 16 shows a structure of a semiconductor device according to a second embodiment.

FIGS. 17-30 are diagrams for describing a manufacturing method of the semiconductor device according to the second embodiment.

### DESCRIPTION OF THE PREFERRED EMBODIMENTS

Semiconductor devices according to embodiments of the present invention and manufacturing methods thereof will now be described with reference to the drawings.

(First Embodiment)

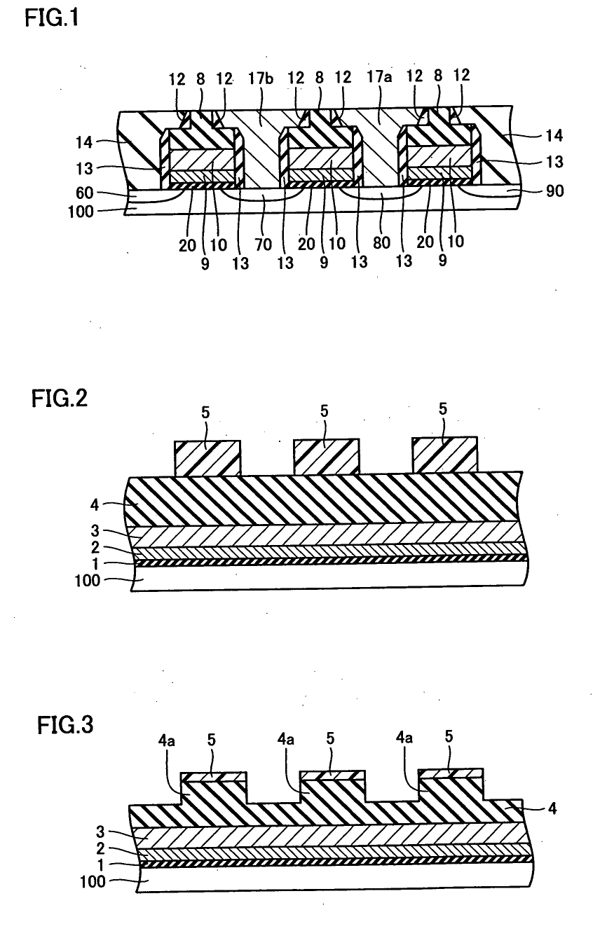

A structure of a semiconductor device according to a first embodiment is described referring to FIG. 1.

In the semiconductor device of this embodiment, impurity diffusion regions 60, 70, 80, 90 forming source/drain regions are formed within a semiconductor substrate 100. A gate insulator film 20 corresponding to a first or second gate insulator film of the present invention is formed on each of three channel regions respectively formed between the four impurity diffusion regions 60, 70, 80, 90.

A polycrystalline silicon film (including an impurity) 9 forming a gate electrode is formed on gate insulator film 20. A tungsten film 10 is formed on polycrystalline silicon film 9. The gate electrode is formed with polycrystalline silicon film 9 and tungsten film 10. The gate electrode corresponds to a first or second gate electrode of the present invention. A plurality of the gate electrodes extend in parallel with each other in a direction vertical to a sheet surface of the drawing.

A silicon nitride film 8 as a hard mask is formed on tungsten film 10. Silicon nitride film 8 has a convex cross-sectional structure. In addition, silicon nitride films 12 and 13 as sidewall insulator films are formed on side surfaces of gate insulator film 20, polycrystalline silicon film 9 and tungsten film 10 and lower and upper side surfaces of convex silicon nitride film 8. A first or second insulator film of the present invention is formed with silicon nitride films 8, 12 and 13.

A contact hole is formed with surfaces of silicon nitride films 12, 8, 13 and semiconductor substrate 100. Contact plugs 17a, 17b as contact plugs of the present invention are respectively embedded in the contact holes. Contact plugs 17a, 17b are connected to a main surface of semiconductor substrate 100.

In the semiconductor device of this embodiment having the structure as shown in FIG. 1, each of contact plugs 17a, 17b has an area of an upper surface larger than that of a lower surface. Therefore, each of plugs connected to the upper surfaces of respective contact plugs 17a, 17b is well connected to each of contact plugs 17a, 17b even if a connection position thereof is deviated for a certain amount. As a result, the characteristic of the semiconductor device is enhanced.

A manufacturing method of the semiconductor device of this embodiment is described referring to FIGS. 2-15. A structure shown in FIG. 2 is first described. An insulator film 1 as a first insulator film for a gate insulator film of the present invention is formed on semiconductor substrate 100. A polycrystalline silicon film 2 including an impurity as a conductive film for a gate electrode of the present invention is formed on insulator film 1. A tungsten film 3 is formed on polycrystalline silicon film 2. A silicon nitride film 4 as a second insulator film for a hard mask of the present invention is formed on tungsten film 3. A resist film 5 as a first resist film of the present invention is formed on silicon nitride film 4 with a prescribed pattern.

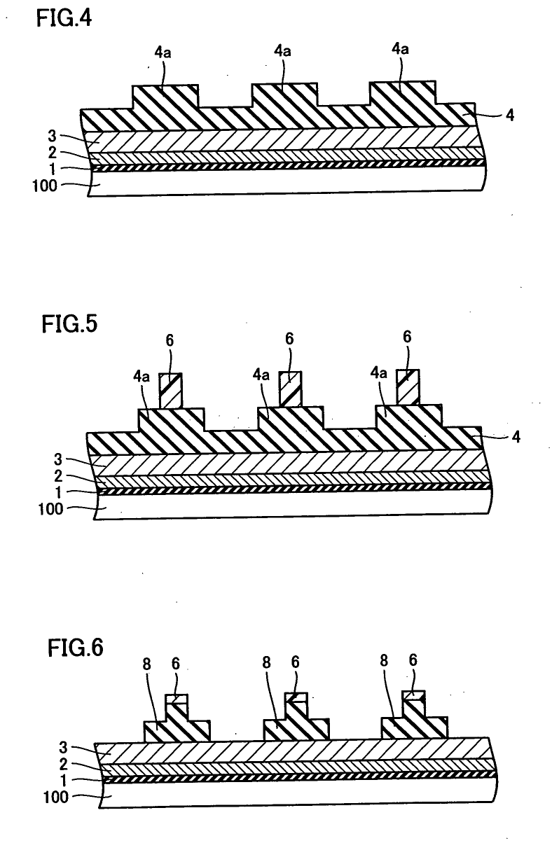

Silicon nitride film 4 is then etched using resist film 5 as a mask. In this step, silicon nitride film 4 is not etched for a whole film thickness thereof. Rather, etching of silicon nitride film 4 is ended at a position on about a half of the film thickness. With this, a projection 4a as a protruding portion of the present invention remains in an upper side of silicon nitride film 4 below resist film 5, as shown in FIG. 3. Resist film 5 is then removed. With this step, a structure as shown in FIG. 4 is obtained.

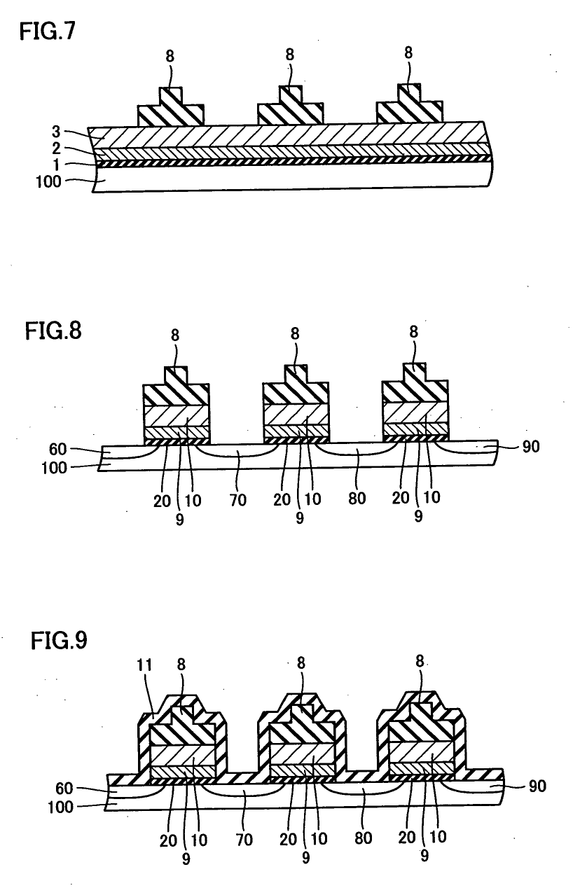

A resist film 6 as a second resist film is formed on projection 4a. Herein, resist film 6 has a width smaller than that of projection 4a. Silicon nitride film 4 is etched using resist film 6 as a mask. With this, a surface of tungsten film 3 is exposed. As a result, a silicon nitride film 8 having a convex cross section is formed as a convex hard mask of the present invention. A structure thereof is shown in FIG. 6. Resist film 6 is then removed. With this step, a structure as shown in FIG. 7 is obtained.

Tungsten film 3, polycrystalline silicon film 2 and insulator film 1 are then removed using silicon nitride film 8 as a hard mask. As a result, gate insulator film 20 as well as polycrystalline silicon film 9 and tungsten film 10 forming a gate electrode are formed, as shown in FIG. 8.

Thereafter, a silicon nitride film 11 is formed to cover all of a surface of semiconductor substrate 100, side surfaces of gate insulator film 20, polycrystalline silicon film 9 and tungsten film 10, and a surface of silicon nitride film 8. Silicon nitride film 11 is then etched back.

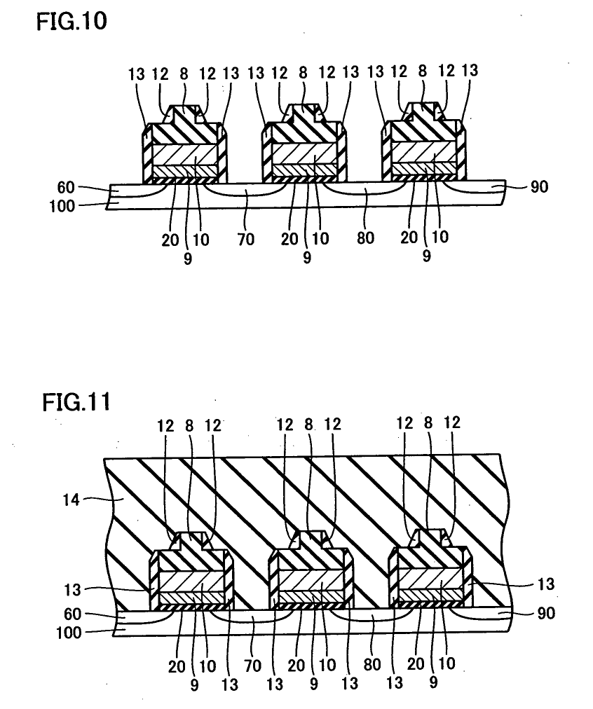

As a result, silicon nitride film 13 as a sidewall film is formed on side surfaces of gate insulator film 20, the gate electrode and a lower portion of convex silicon nitride film 8, as shown in FIG. 10. In addition, silicon nitride film 12 as a sidewall film is formed on a side surface of an upper portion of convex silicon nitride film 8.

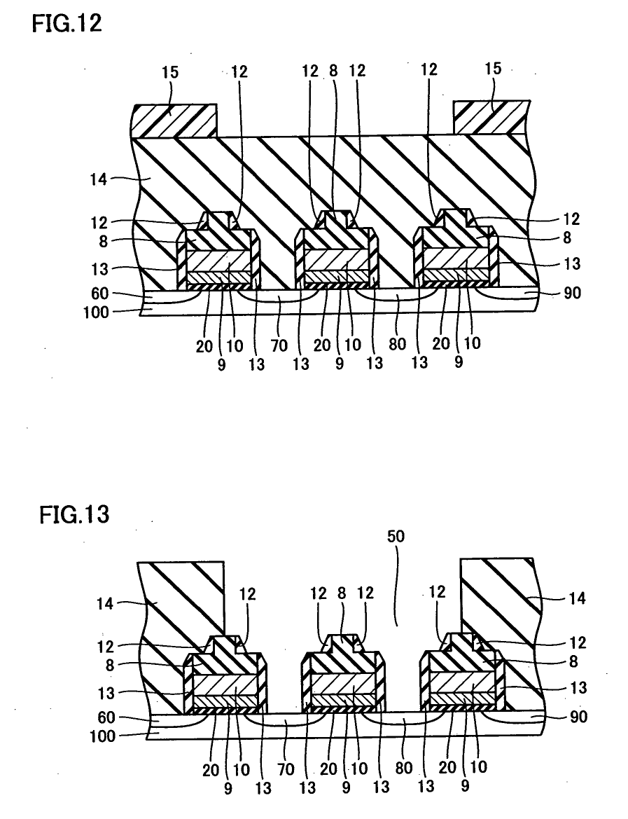

A silicon oxide film 14 made of BPSG (Boro-Phospho-Silicate Glass) is then formed so as to a whole surface of the semiconductor substrate. With this step, a structure as shown in FIG. 11 is obtained. Thereafter, a resist film 15 having a prescribed pattern is formed on silicon oxide film 14, as shown in FIG. 12.

Silicon oxide film 14 is etched using resist film 15 as a mask to expose the main surface of semiconductor substrate 100. As silicon oxide film 14 has a selection ratio larger than that of the silicon nitride film, a contact hole 50 is formed on surfaces of silicon nitride films 8, 12, 13 in a self-aligning manner. With this step, surfaces of impurity diffusion regions 70, 80 are exposed. A structure thereof is shown in FIG. 13.

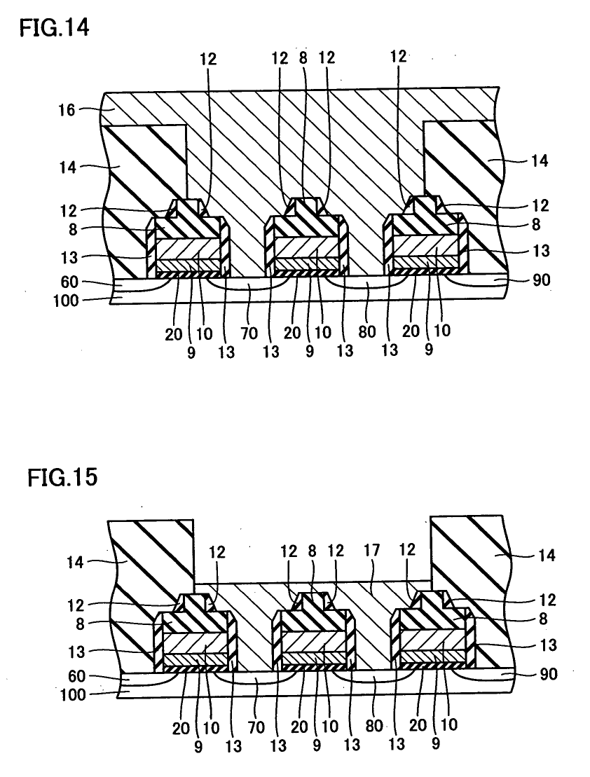

Thereafter, contact hole 50 is filled with a polycrystalline silicon film 16 including an impurity, as shown in FIG. 14. Polycrystalline silicon film 16 is then etched back to form a polycrystalline silicon film 17, as shown in FIG. 15. Silicon oxide film 14 and polycrystalline silicon film 17 are etched back to form contact plugs 17a, 17b each formed with the polycrystalline silicon film. With this step, a structure as shown in FIG. 1 is obtained.

(Second Embodiment)

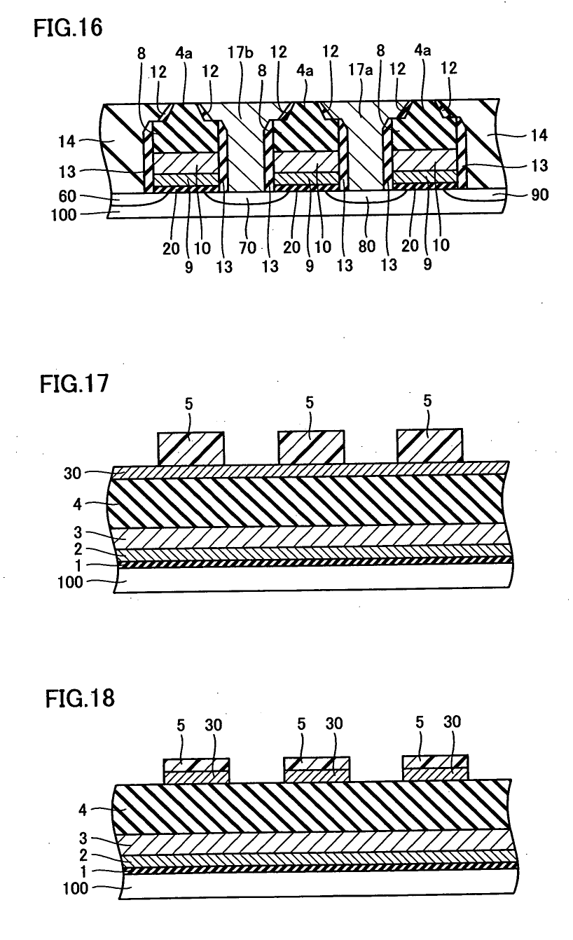

A structure of a semiconductor device according to a second embodiment is described referring to FIG. 16. As shown in FIG. 16, the semiconductor device of this embodiment has a similar structure as the semiconductor device of the first embodiment described with reference to FIG. 1. A form of silicon nitride film 8, however, is slightly different in the semiconductor device of this embodiment.

Though silicon nitride film 8 shown in FIG. 1 has the side surface of the upper portion nearly vertical to the main surface of semiconductor substrate 100 in the convex cross section thereof, the side surface of the upper portion of convex silicon nitride film 8 of the semiconductor device according to this embodiment is oblique to the main surface of semiconductor substrate 100. This is caused by a manufacturing method described below. Effects similar to those obtained with the semiconductor device of the first embodiment are also obtained with the semiconductor device of this embodiment.

The manufacturing method of the semiconductor device of this embodiment is described referring to FIGS. 17-30.

A structure shown in FIG. 17 is first described. The structure shown in FIG. 17 is similar to that of the manufacturing step of the semiconductor device of the first embodiment described referring to FIG. 2. Resist film 5, however, is not formed directly on silicon nitride film 4, and a polycrystalline silicon film 30 of the present invention is formed on silicon nitride layer 4. Resist film 5 of the present invention having a prescribed pattern is formed on polycrystalline silicon film 30.

Polycrystalline silicon film 30 is then etched using resist film 5 as a mask, as shown in FIG. 18. In this step, an upper portion of resist film 5 is etched and a thickness of resist film 5 decreases. Silicon nitride film 4 is wet-etched using resist film 5 and polycrystalline silicon film 30 as a mask.

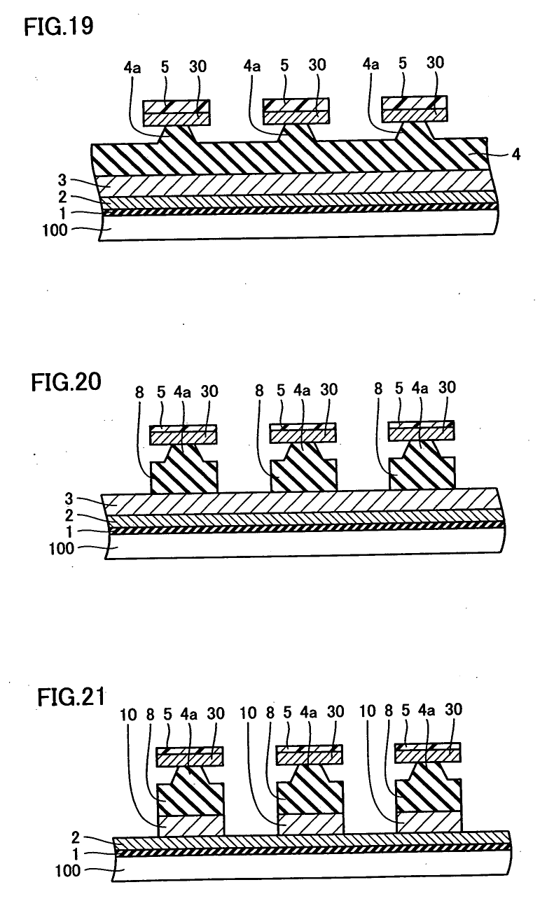

As the wet etching is isotropic etching, projection 4a as a protruding portion of the present invention is formed in an upper portion of silicon nitride film 4, as shown in FIG. 19. Projection 4a is oblique to the main surface of semiconductor substrate 100. Though projection 4a is formed with wet etching in this embodiment, dry etching may be used as long as it is isotropic. Projection 4a is formed better with dry etching than with wet etching.

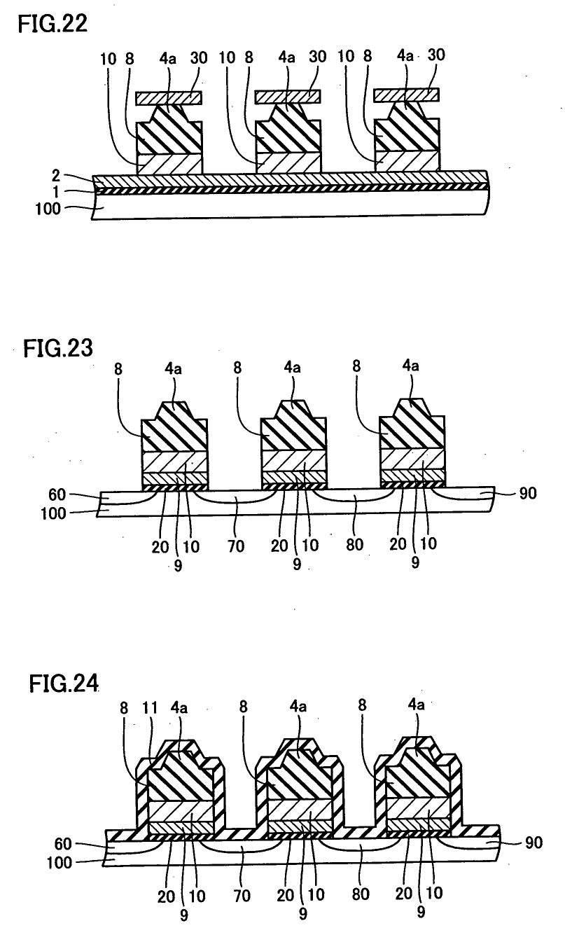

Thereafter, silicon nitride film 4 is anisotropically etched using resist film 5 and polycrystalline silicon film 30 as a mask. With this step, silicon nitride film 8 having a convex cross section is formed. A structure thereof is shown in FIG. 20. As shown in FIG. 21, tungsten film 10 is then formed by etching tungsten film 3 using resist film 5, polycrystalline silicon film 30 and silicon nitride film 8 as a mask. Resist film 5 is removed to obtain a structure shown in FIG. 22. Polycrystalline silicon films 2, 30 and insulator film 1 are etched using silicon nitride film 8 and tungsten film 10 as a mask, as shown in FIG. 22.

With this step, the main surface of semiconductor substrate 100 is exposed. As a result, polycrystalline silicon film 9 and tungsten film 10 forming a gate electrode and gate insulator film 20 are formed. A structure thereof is shown in FIG. 23.

As shown in FIG. 24, silicon nitride film 11 is then formed to cover all of the surface of semiconductor substrate 100, the side surfaces of gate insulator film 20, polycrystalline silicon film 9 and tungsten film 10, and the surface of silicon nitride film 8.

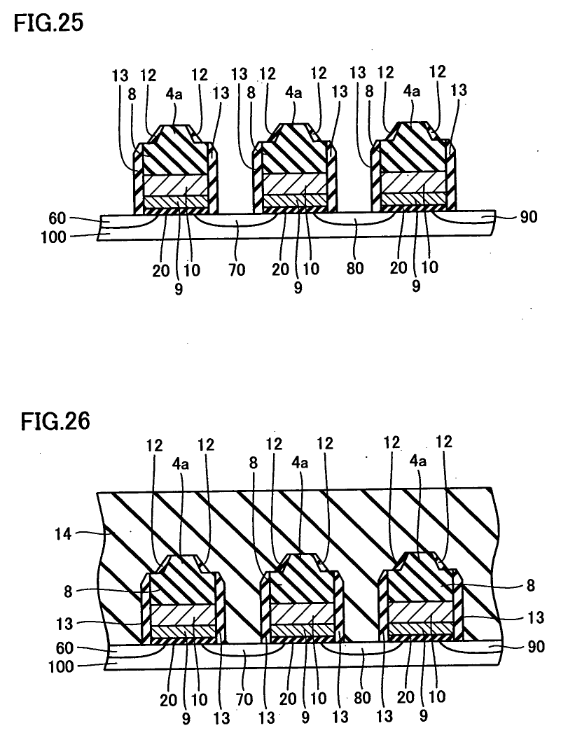

Silicon nitride film 11 is then etched back to obtain a structure shown in FIG. 25. In the structure shown in FIG. 25, silicon nitride film 13 is formed to cover the side surfaces of gate insulator film 20, polycrystalline silicon film 9 and tungsten film 10 forming the gate electrode, and a lower portion of convex silicon nitride film 8. In addition, silicon nitride film 12 is formed on a side surface of an upper portion of convex silicon nitride film 8.

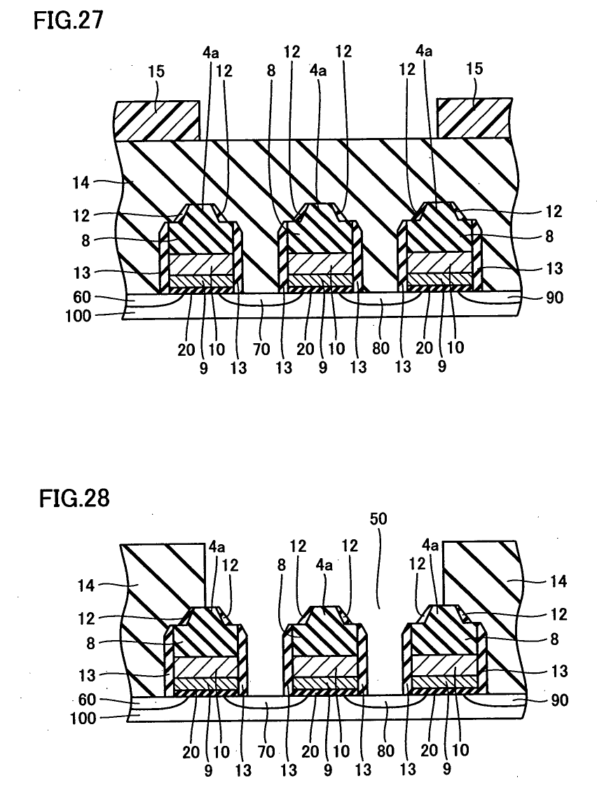

As shown in FIG. 26, silicon oxide film 14 is then formed to cover the whole surface of semiconductor substrate 100. Thereafter, resist film 15 having a prescribed pattern is formed on silicon oxide film 14. A structure thereof is shown in FIG. 27.

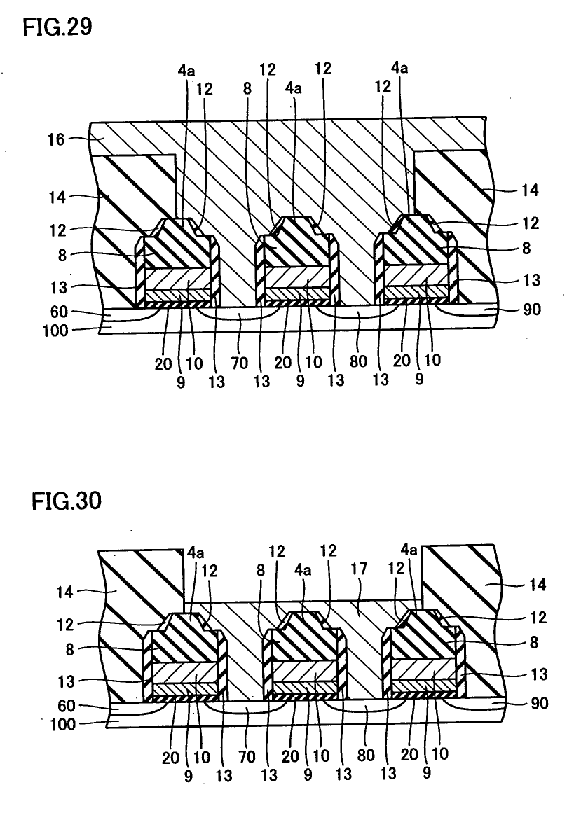

Silicon oxide film 14 is etched using resist film 15 as a mask. As silicon oxide film 14 has a selection ratio larger than that of silicon nitride films 8, 12, 13, contact hole 50 is formed for silicon nitride films 8, 12, 13 in a self-aligning manner. A structure thereof is shown in FIG. 28. Polycrystalline silicon film 16 including an impurity is formed so as to fill contact hole 50. A structure thereof is shown in FIG. 29.

As shown in FIG. 30, polycrystalline silicon film 16 is then etched back to form polycrystalline silicon film 17. Surfaces of silicon oxide film 14 and polycrystalline silicon film 17 are further etched back to obtain the structure shown in FIG. 16.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a semiconductor substrate;
a first gate insulator film and a first gate electrode formed on the semiconductor substrate;
a second gate insulator film and a second gate electrode formed on said semiconductor substrate and provided to extend in parallel with an extending direction of said first gate insulator film and said first gate electrode;
a first insulator film formed to cover surfaces of said first gate insulator film and said first gate electrode;
a second insulator film formed to cover surfaces of said second gate insulator film and said second gate electrode; and
a contact plug connected to an impurity diffusion region of said semiconductor substrate within a contact hole formed with surfaces of said first insulator film and said second insulator film, wherein
an area of said contact plug in a direction parallel to a main surface of said semiconductor substrate is larger on an upper surface than on a lower surface.

2. A method of manufacturing a semiconductor device, comprising the steps of:
forming a first insulator film as a gate insulator film on a semiconductor substrate;
forming a conductive film as a gate electrode on the first insulator film;
forming a second insulator film as a hard mask on the conductive film;
forming a first resist film having a prescribed pattern on the second insulator film;
removing a portion of said second insulator film from an upper surface to a prescribed depth using the first resist film as a mask to form a portion protruding in a direction to leave from a main surface of said semiconductor substrate in said second insulator film;
removing said first resist film;
forming a second resist film on an upper surface of said protruding portion with a width smaller than that of the upper surface;
etching said second insulator film using said second resist film as a mask to expose a surface of said conductive film and form a convex hard mask; and
etching said conductive film and said first insulator film using the convex hard mask as a mask to expose said semiconductor substrate.

3. A method of manufacturing a semiconductor device, comprising the steps of:
forming a first insulator film as a gate insulator film on a semiconductor substrate;
forming a conductive film as a gate electrode on the first insulator film;
forming a second insulator film as a hard mask on the conductive film;
forming a polycrystalline silicon film on the second insulator film;
forming a resist film having a prescribed pattern on the polycrystalline silicon film;
anisotropically etching said polycrystalline silicon film using the resist film as a mask to expose said second insulator film;
isotropically etching said second insulator film using said resist film and said anisotropically-etched polycrystalline silicon film as a mask to form a projecting portion in said second insulator film below said anisotropically-etched polycrystalline silicon film;
anisotropically etching said second insulator film using said resist film and said anisotropically-etched polycrystalline silicon film as a mask to form said second insulator film into convex shape; and
removing said resist film and said anisotropically-etched polycrystalline silicon film.
